(19) United States
(12) Patent Application Publication
(10) Pub. No.: US 2013/0062644 A1
(43) Pub. Date: Mar. 14, 2013

(54) SEMICONDUCTOR LIGHT EMITTING DEVICE AND METHOD FOR MANUFACTURING SAME

(71) Applicant: Naoya USHIYAMA, Fukuoka-ken (JP)

(72) Inventor: Naoya USHIYAMA, Fukuoka-ken (JP)

(73) Assignee: Kabushiki Kaisha Toshiba, Tokyo (JP)

(21) Appl. No.: 13/424,354

(22) Filed: Mar. 19, 2012

(30) Foreign Application Priority Data
Sep. 14, 2011 (JP) 2011-200544

(51) Int. Cl. H01L 33/60; H01L 33/56

(52) U.S. Cl. 257/98; 438/27; 257/E33.072; 257/E33.059

(57) ABSTRACT

According to one embodiment, a method for manufacturing a semiconductor light emitting device includes: preparing a metal plate including first and second frames, the first frames being disposed alternately with the second frames to be apart from the second frames, a light emitting element being affixed to each of the first frames and connected via a metal wire to an adjacent second frame; forming a first resin on a first major surface of the metal plate to cover the first and second frames, and the light emitting elements; making a trench from a second major surface side; and filling a second resin into an interior of the trench from the first major surface side. The method further includes forming the resin packages by dividing the second resin along the trench, an outer edge of the first resin being covered with the second resin.

### CROSS-REFERENCE TO RELATED APPLICATIONS

This application is based upon and claims the benefit of priority from the prior Japanese Patent Application No. 2011-200544, filed on Sep. 14, 2011; the entire contents of which are incorporated herein by reference.

### FIELD

Embodiments described herein relate generally to a semiconductor light emitting device and a method for manufacturing the same.

### BACKGROUND

Semiconductor light emitting devices have low power consumption and long lives and are beginning to be used in various applications such as display devices, illumination appliances, and the like. For example, a semiconductor light emitting device in which a light emitting diode (LED) is mounted can be small and can be driven by a low voltage; and the control of the light emission also is easy. Therefore, there is a wide range of applications for such a semiconductor light emitting device.

On the other hand, technology is necessary to reduce the power consumption by efficiently utilizing the light emitted from semiconductor light emitting devices. For example, in the package of a semiconductor light emitting device in which an LED is mounted, an enclosure is provided to control the light distribution by reflecting the light emission of the LED. However, there are cases where the enclosure which is made of a resin undergoes thermal denaturation when mounting the light emitting element and the other components in the interior of the package; and the light emission intensity may decrease. It is also problematic that the formation of the enclosure itself increases the manufacturing cost. Therefore, a semiconductor light emitting device and a method for manufacturing the semiconductor light emitting device are necessary to avoid the thermal denaturation of the resin package and realize inexpensive manufacturing.

### BRIEF DESCRIPTION OF THE DRAWINGS

FIG. 1 is a perspective view that schematically illustrates a semiconductor light emitting device according to a first embodiment;

FIGS. 2A and 2B are cross-sectional views that schematically illustrate the manufacturing processes of the semiconductor light emitting device according to the first embodiment;

FIGS. 3A and 3B are cross-sectional views that schematically illustrate the manufacturing processes following FIGS. 2A and 2B;

FIGS. 4A to 4C are cross-sectional views that schematically illustrate the manufacturing processes following FIGS. 3A and 3B;

FIGS. 5A to 5D are schematic views illustrating a structure of the semiconductor light emitting device according to the first embodiment, wherein FIG. 5A is a plan view, FIG. 5B is a front view, FIG. 5C is a side view, and FIG. 5D is a bottom plan view;

FIGS. 6A to 6D are schematic views illustrating a structure of the semiconductor light emitting device according to a second embodiment, wherein FIG. 6A is a plan view, FIG. 6B is a front view, FIG. 6C is a side view, and FIG. 6D is a bottom plan view;

FIGS. 7A and 7B are cross-sectional views that schematically illustrate the processes according to the second embodiment;

FIGS. 8A to 8C are cross-sectional views that schematically illustrate the manufacturing processes following FIGS. 7A and 7B;

FIGS. 9A and 9B are schematic views illustrating lead frames of the semiconductor light emitting device; and

FIGS. 10A to 10C illustrate a formation process of a vacuum molding.

### DETAILED DESCRIPTION

In general, according to one embodiment, a method for manufacturing a semiconductor light emitting device, includes: preparing a metal plate including a plurality of first frames and a plurality of second frames, the first frames being disposed alternately with the second frames to be apart from the second frames, a light emitting element being affixed to each of the first frames and connected via a metal wire to an adjacent second frame; forming a first resin on a first major surface of the metal plate to cover the first frames, the second frames, and the light emitting elements; making a trench from a second major surface side opposite to the first major surface to delineate resin packages by dividing the metal plate and the first resin; filling a second resin into an interior of the trench from the first major surface side; and forming the resin packages by dividing the second resin along the trench, an outer edge of the first resin being covered with the second resin.

In general, according to another embodiment, a semiconductor light emitting device, includes: a first frame; a light emitting element affixed to the first frame; a second frame disposed apart from the first frame, the second frame being electrically connected to an electrode of the light emitting element via a metal wire; and a resin package including a first resin and a second resin, the first resin being configured to cover the light emitting element, the first frame, and the second frame, the second resin being configured to cover an outer edge of the first resin and reflect light emitted by the light emitting element, a cross-sectional area of the first resin in a cross-section parallel to a front surface of the first frame being configured to enlarge from the front surface of the first frame toward a front surface of the first resin opposite to the first frame, a back surface of the first frame and a back surface of the second frame being exposed at one surface of the resin package, the back surface of the first frame being on a side opposite to the front surface of the first frame having the affixed light emitting element, the back surface of the second frame being on a side opposite to the front surface of the second frame having the connected metal wire, the first frame and the second frame being positioned on an inner side of an outer edge of the resin package when viewed in plan by projection onto a plane parallel to the one surface.

Embodiments of the invention will now be described with reference to the drawings. Similar portions in the drawings are marked with like numerals; a detailed description thereof is omitted as appropriate; and portions that are different are described. For convenience in the specification, there are cases where the configuration of the semiconductor light emitting device is described based on an XYZ orthogonal coordinate system illustrated in the drawings.

### First Embodiment

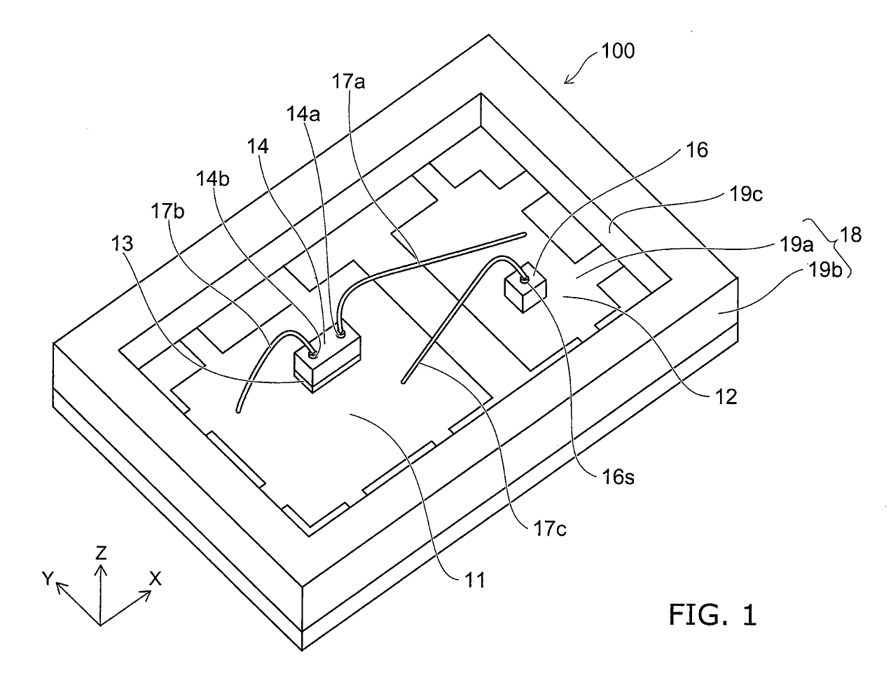

FIG. 1 is a perspective view that schematically illustrates a semiconductor light emitting device 100 according to a first embodiment. The semiconductor light emitting device 100 includes a light emitting element 14, a peripheral component 16 of the light emitting element 14, and a resin package 18 that contains the light emitting element 14 and the peripheral component 16. The light emitting element 14 is, for example, an LED; and the peripheral component 16 is, for example, a Zener diode (ZD). The ZD 16 is provided to protect the LED 14. The LED 14 and the ZD 16 are mounted respectively to a leadframe 11 which is a first frame and a leadframe 12 which is a second frame and are sealed in the interior of the resin package 18 covering the leadframes 11 and 12.

In the specification, the concept of covering includes both the case of the covering component being in contact with the covered component and the case of not being in contact. For example, another material may be interposed between a first resin 19a and the LED 14, the ZD 16, and the leadframes 11 and 12 that are covered with the first resin 19a.

As illustrated in FIG. 1, the leadframe 12 and the leadframe 11 are disposed to be apart from each other in the X direction. The LED 14 is affixed to the front surface of the leadframe 11; and the ZD 16 is affixed to the front surface of the leadframe 12. A metal wire 17a connects a p-electrode 14a of the LED 14 to the leadframe 12; and a metal wire 17b connects an n-electrode 14b of the LED 14 to the leadframe 11. On the other hand, a metal wire 17c connects an electrode 16s of the ZD 16 to the leadframe 11.

The leadframes 11 and 12 are, for example, flat plates arranged in the same plane and are made of the same conductive material. For example, the leadframes 11 and 12 are copper plates with silver plating performed on the front surfaces and the back surfaces of the leadframes 11 and 12. Thereby, light radiated by the LED 14 is reflected.

The resin package 18 includes the first resin 19a and a second resin 19b, where the first resin 19a covers the LED 14, the ZD 16, the leadframe 11, and the leadframe 12 and the second resin 19b covers the outer edge of the first resin 19a. The first resin 19a transmits the light radiated by the LED 14. On the other hand, the second resin 19b provided around the outer edge of the first resin 19a includes a reflective material configured to reflect the light of the LED 14 and reflects the light of the LED 14 that is radiated in the X direction and the Y direction.

Thus, the LED 14 is disposed in a state of the leadframes 11 and 12, which are configured to reflect the light radiated by the LED 14, and the second resin 19b, which functions as an enclosure, being provided around the LED 14. Thereby, the light of the LED 14 is radiated in the Z direction; and the directivity and the light output of the semiconductor light emitting device 100 are improved. For example, it is possible to control the directivity by changing the reflectance by controlling the amount of the reflective material included in the second resin. Also, the directivity may be controlled by changing the thickness of the second resin 19b in the X direction and the Y direction.

The material of the LED 14 used in this embodiment is, for example, a semiconductor layer including gallium nitride (GaN) and the like stacked on a sapphire substrate. The chip has, for example, a rectangular parallelepiped configuration; and the p-electrode 14a and the n-electrode 14b are provided on the upper surface of the chip. For example, the LED 14 radiates blue light when a drive current is caused to flow between the p-electrode 14a and the n-electrode 14b.

The LED 14 is affixed via a die mount material 13 that is bonded to the front surface of the leadframe 11 to cover the front surface of the leadframe 11. In the LED 14 according to this embodiment, the active region (the light emitting portion) is electrically isolated from the back surface of the LED chip by an insulative substrate (the sapphire substrate). Accordingly, the die mount material 13 may be conductive or insulative. The die mount material 13 may include, for example, a bonding agent made of a silver paste or a transparent resin paste.

On the other hand, the affixation of the ZD 16 includes, for example, a eutectic mount which is bonded by forming a silicide between the frame front surface and the silicon surface of the chip back surface. Therefore, the temperature of the die bonding is a high temperature; and in the case where, for example, the enclosure is formed beforehand on the frame that is used, there are cases where the reflectance is reduced by denaturation of the resin included in the enclosure and the light output decreases.

Conversely, in this embodiment, the enclosure is formed after affixing the LED 14 and the ZD 16 to the leadframes 11 and 12. Thereby, the ZD 16 can be affixed to the leadframe 12 at a high temperature. Instead of a silver paste or a bonding agent, the light emitting element 14 also can be affixed using solder or eutectic solder. The bonding is possible at a high temperature even in the case where another peripheral component is used instead of the ZD 16. In other words, it is possible to use a component that is affixed to at least one selected from the leadframe 11 and the leadframe 12 at a higher temperature than the affixing of the LED 14.

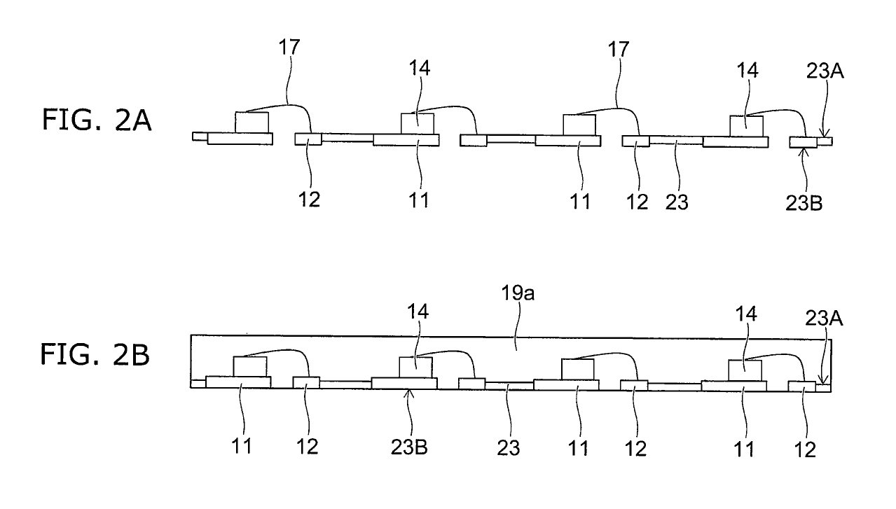

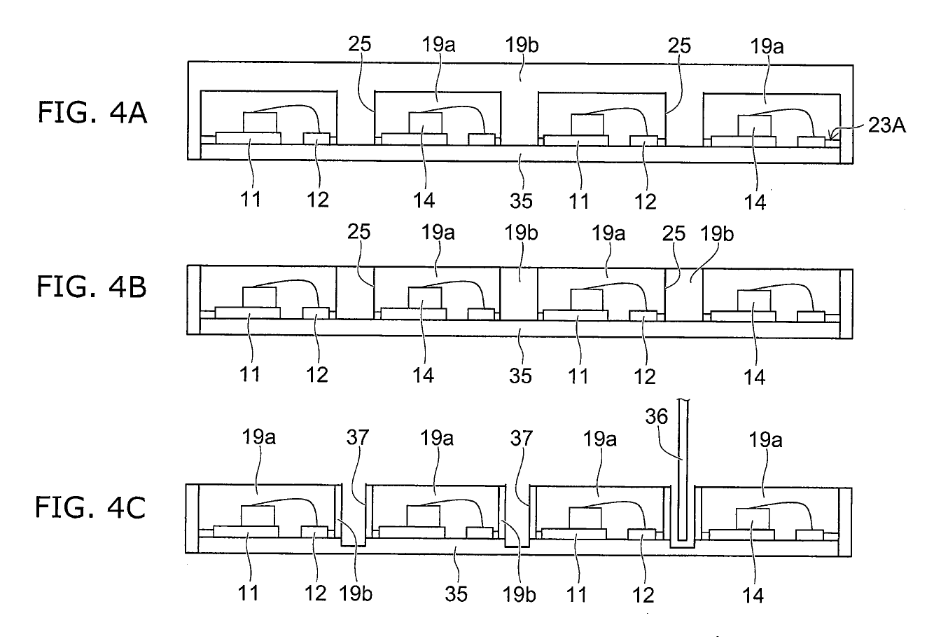

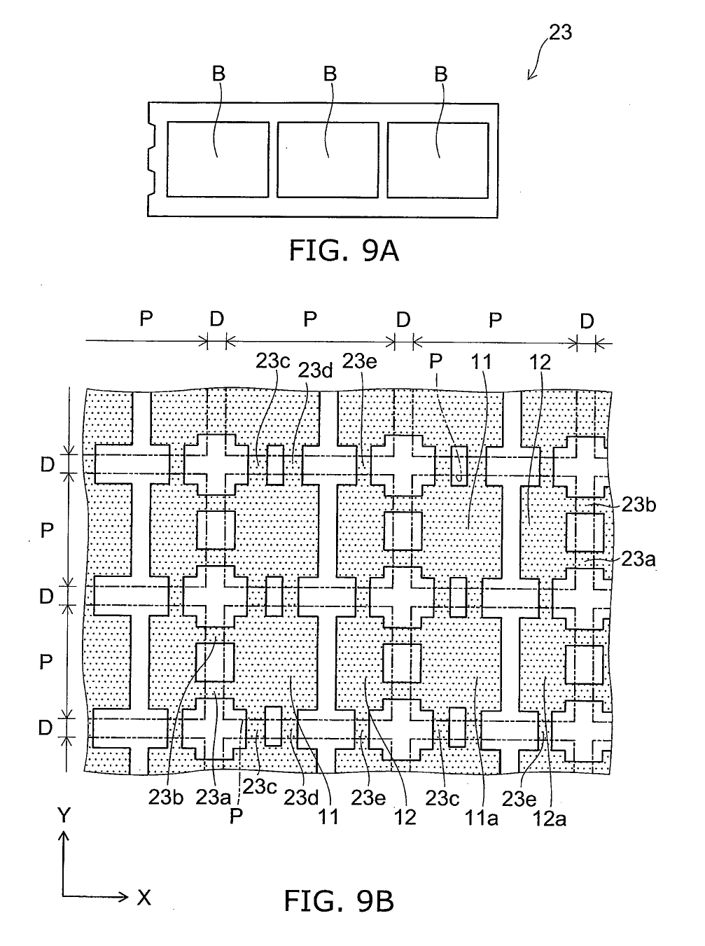

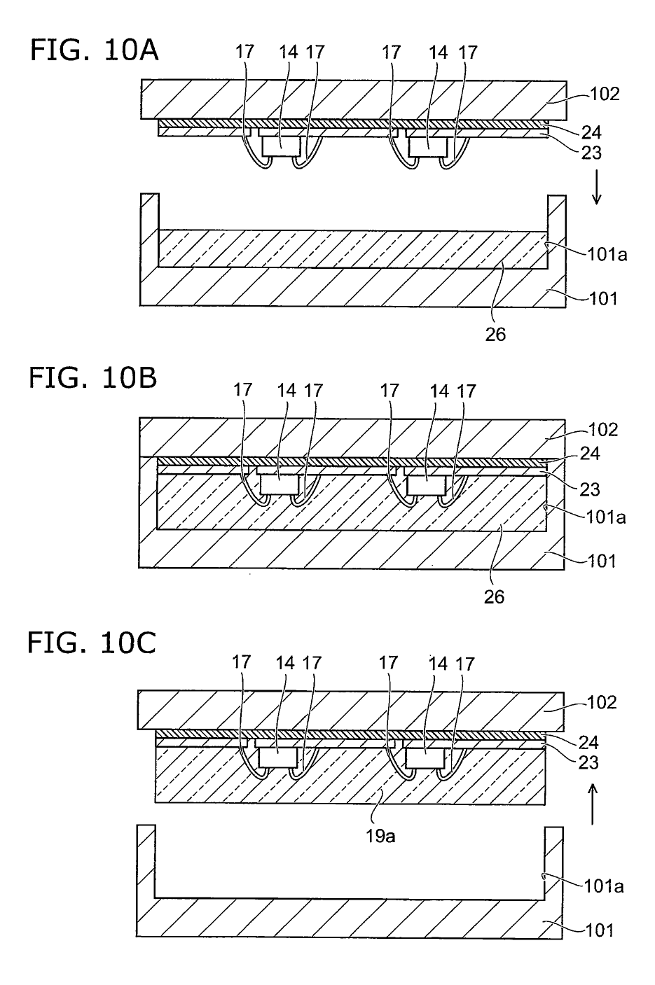

A method for manufacturing the semiconductor light emitting device 100 will now be described with reference to FIG. 2A to FIG. 4C, FIGS. 9A and 9B, and FIGS. 10A to 10C. FIG. 2A to FIG. 4B are cross-sectional views that schematically illustrate the manufacturing processes of the semiconductor light emitting device 100. FIGS. 9A and 9B are schematic views illustrating the leadframes of the semiconductor light emitting device 100. FIGS. 4A to 4C are cross-sectional views that schematically illustrate the processes of the vacuum forming.

First, as illustrated in FIG. 2A, the LED 14 is affixed to the front surface of the leadframe 11; and the ZD 16 is affixed to the front surface of the leadframe 12. Then, the metal wires 17 are bonded respectively from the electrodes to the leadframes 11 and 12. For simplicity in FIG. 2A to FIG. 4C and FIGS. 9A and 9B, the ZD 16 and the metal wire 17b that connects the LED 14 to the leadframe 11 are not illustrated.

The leadframes 11 and 12 are formed in a metal plate 23 made of, for example, copper. As illustrated in FIG. 9A, for example, three blocks B are set in the metal plate 23. For example, about 1000 frame pairs P (the leadframes 11 and 12) are formed in each of the blocks B.

As illustrated in FIG. 9B, the frame pairs P are arranged in a matrix configuration in each of the blocks B. The region between mutually-adjacent frame pairs P is a dicing region D having a lattice configuration. Such a frame pattern is manufactured by, for example, selective etching of the metal plate 23. The formation also is possible by stamping.

Each of the frame pairs P includes the mutually-separated leadframes 11 and 12. The multiple leadframes 11 and the multiple leadframes 12 are disposed alternately in the X direction. In the dicing region D, mutually-adjacent frame pairs P are connected by linking portions (suspension pins) 23a to 23e.

For example, focusing now on one frame pair P positioned in the center of FIG. 9B, the leadframe 11 is linked via the linking portions 23a and 23b to the leadframe 12 of the adjacent frame pair P positioned in the −X direction as viewed from this frame pair P. On the other hand, in the Y direction, the leadframes 11 included in mutually-adjacent frame pairs P are linked to each other via the linking portions 23c and 23d. Similarly, in the Y direction, the leadframes 12 included in the mutually-adjacent frame pairs P are linked to each other via the linking portion 23e.

The linking portions 23a to 23e are formed to be thinner than the leadframes 11 and 12 by performing half-etching from a back surface 23B (a second major surface) side of the metal plate 23. For example, patterning is performed to half of the thickness of the leadframes 11 and 12.

Then, as illustrated in FIG. 2B, the LED 14, the ZD 16, the leadframe 11, and the leadframe 12 are covered by forming the first resin 19a on a front surface 23A (a first major surface) side of the metal plate 23.

FIGS. 10A to 10C illustrate a formation process of the first resin 19a. First, as illustrated in FIG. 10A, a reinforcing sheet 24 made of polyimide is adhered to the back surface of the metal plate 23; and the metal plate 23 is mounted to the engagement surface (the lower surface) of an upper die 102 via the reinforcing sheet 24.

A lower die 101 that corresponds to the upper die 102 has a recess 101a in the engagement surface (the upper surface) of the lower die 101. Then, a resin material 26 used to form the first resin 19a is filled into the recess 101a. The first resin 19a may include, for example, a resin having a main component of silicone.

A prescribed fluorescer may be dispersed in the resin material 26. For example, a liquid or semi-liquid resin material 26 including a fluorescer is prepared by mixing the fluorescer into a transparent silicone resin and by stirring. In the case where the fluorescer is mixed into a transparent silicone resin, the dispersion can be uniform by using a thixotropic agent. Then, the resin material 26 into which the fluorescer is dispersed is filled into the recess 101a using a dispenser.

Then, as illustrated in FIG. 10B, the upper die 102 and the lower die 101 are closed. Thereby, the resin material 26 is adhered to the front surface of the metal plate 23. At this time, vacuum evacuation is performed between the upper die 102 and the lower die 101 such that the resin material 26 uniformly covers the LED 14, the ZD 16, the metal wire 17, and the leadframes 11 and 12 without gaps.

As described above, the linking portions 23a to 23e that link the mutually-adjacent leadframes 11 and leadframes 12 are patterned to be half of the thickness of the leadframes 11 and 12 at the back surface 23B on the side opposite to the front surface 23A which is the side from which the first resin 19a is filled. Therefore, the first resin 19a is formed to extend around to the back surface side of the linking portions 23a to 23e; and the bonding strength between the first resin 19a and the leadframes 11 and 12 is increased.

Then, after curing the resin material 26 by increasing the temperature of the die, the first resin 19a is released from the recess 101a by opening the upper die 102 and the lower die 101 as illustrated in FIG. 10C. Continuing, the metal plate 23 is removed from the upper die 102; and the reinforcing sheet 24 is peeled from the back surface of the metal plate 23. Thereby, the first resin 19a can be formed on the front surface 23A of the metal plate 23.

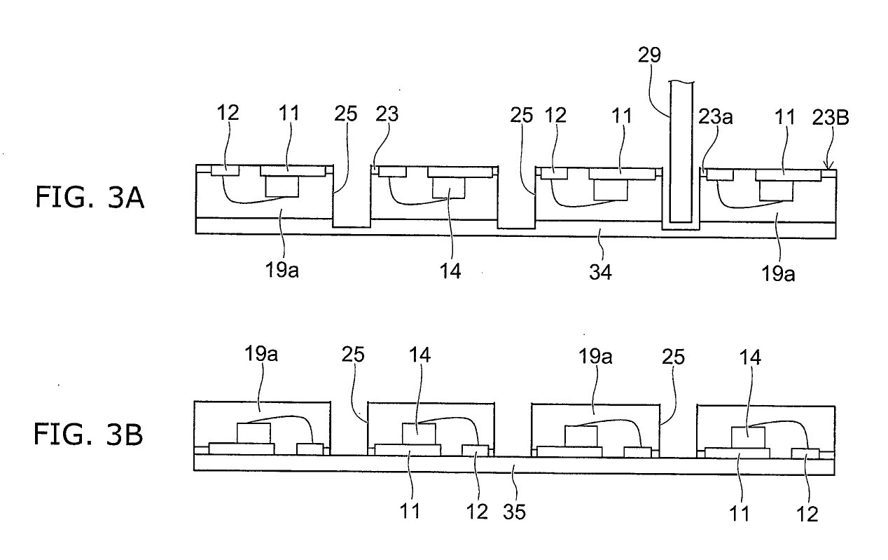

Continuing, a dicing sheet 34 is adhered to the front surface of the first resin 19a; and the reinforcing sheet 24 is peeled from the back surface 23B (the second major surface) of the metal plate 23. Continuing as illustrated in FIG. 3A, a trench 25 is made along the outer circumferences of the resin packages 18 from the back surface side of the metal plate 23 to divide the linking portions 23a to 23e and the first resin 19a along the dicing region D. Here, for example, a dicing blade 29 may be used.

Then, as illustrated in FIG. 3B, another dicing sheet 35 is adhered to the divided back surface of the metal plate 23; and the dicing sheet 34 is peeled from the front surface of the first resin 19a. Thereby, the metal plate 23 is transferred in the state of the front surface 23A (the first major surface) side being oriented upward.

Continuing as illustrated in FIG. 4A, the second resin 19b is formed from the front surface 23A side of the metal plate 23 to cover the first resin 19a and the trench 25. Thereby, the second resin 19b is filled into the interior of the trench 25. In such a case as well, the vacuum forming illustrated in FIGS. 10A to 10C may be used.

The second resin 19b may include, for example, a white resin including titanium oxide as a reflective material. Further, it is favorable for the first resin 19a and the second resin 19b to include the same material to increase the adhesion between the first resin 19a and the second resin 19b.

The second resin 19b may include, for example, the same silicone resin as the first resin 19a. For example, a fine powder of titanium oxide is dispersed as the reflective material.

Then, as illustrated in FIG. 4B, the second resin 19b formed on the upper surface of the first resin 19a is removed to leave the second resin 19b in the trench 25. For example, the front surface of the first resin 19a is exposed by polishing or grinding the second resin 19b.

Continuing as illustrated in FIG. 4C, the second resin 19b is cut along the extension directions of the trench 25. In such a case, the dicing blade 36 that is used has a narrower width than the dicing blade 29 illustrated in FIG. 3A. Thereby, the resin packages 18 can be formed by dividing the second resin 19b at the inner sides of the trench 25 such that the outer edges of the first resin 19a are covered with the second resin 19b.

In the process recited above, the second resin 19b may be filled after increasing the width of the trench 25 by expanding the dicing sheet 35. Thereby, the width of the second resin 19b can be wider.

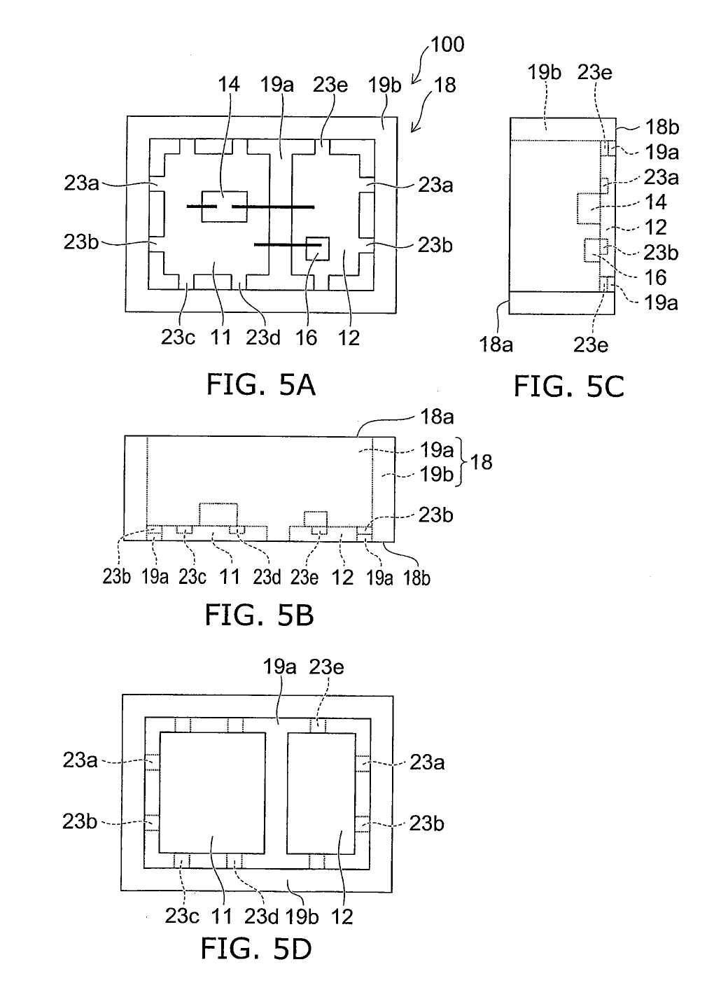

FIGS. 5A to 5D are schematic views illustrating details of the structure of the semiconductor light emitting device 100 manufactured by the manufacturing method recited above. FIG. 5A is a plan view; FIG. 5B is a front view; FIG. 5C is a side view; and FIG. 5D is a bottom plan view.

As illustrated in FIG. 5A to FIG. 5C, the first resin 19a covers the leadframe 11 to which the LED 14 is affixed and the leadframe 12 to which the ZD 16 is affixed; and the second resin 19b is provided to cover the outer edge of the first resin 19a. The light of the LED 14 is reflected by the leadframes 11 and 12 and the second resin 19b and is radiated from an upper surface 18a of the resin package 18.

The multiple linking portions 23a to 23e extend between the leadframes 11 and 12 and the second resin 19b; and the first resin 19a is filled between the multiple linking portions 23a to 23e. As illustrated in FIG. 5B and FIG. 5C, the first resin 19a also extends around to the back surfaces of the linking portions 23a to 23e to increase the bonding strength between the first resin 19a and the leadframes 11 and 12.

As illustrated in FIG. 5D, the back surface of the leadframe 11, which is on the side opposite to the front surface of the leadframe 11 to which the LED is affixed, and the back surface of the leadframe 12, which is on the side opposite to the front surface of the leadframe 12 to which the metal wire 17 is bonded, are exposed at a back surface 18b which is one surface of the resin package 18. The leadframe 11 and the leadframe 12 that include the linking portions (the suspension pins) 23a to 23e are positioned on the inner side of the outer edge of the resin package 18 when viewed in plan by projection onto a plane parallel to the back surface 18b.

In this embodiment, the end surfaces of the linking portions (the suspension pins) 23a to 23e are not exposed at the side surface of the resin package 18. Accordingly, the semiconductor light emitting device 100 is mounted to the circuit substrate in a state in which the entire package is covered with an insulative resin. Therefore, short failures can be suppressed; and high-density mounting of the semiconductor light emitting device 100 and the circuit components is possible.

In this embodiment, it is possible to easily manufacture the resin package 18 including the enclosure by, for example, performing vacuum forming twice. Thereby, the manufacturing cost can be reduced. The high-temperature mounting of the light emitting elements and the peripheral components is possible because the resin package 18 is formed after mounting the light emitting elements and the peripheral components of the light emitting elements. Thereby, it is possible to increase the adhesion strength of the light emitting elements and the peripheral components to the leadframes as well as reduce the contact resistance. Thereby, the reliability of the semiconductor light emitting device 100 can be increased.

As described above, the fluorescer may be dispersed in the first resin 19a; and the wavelength of the light radiated from the LED 14 may be converted. For example, by dispersing a silicate-based fluorescer in the first resin 19a, a portion of the blue light radiated from the LED 14 is absorbed and yellow fluorescence is radiated. Thereby, the semiconductor light emitting device 100 emits white light by the mixing of the blue light radiated by the LED 14 and the yellow light radiated from the fluorescer.

Other than using a silicate-based fluorescer to emit a yellow fluorescence, for example, a silicate-based fluorescer, a YAG-based fluorescer, a sialon-based red fluorescer, a green fluorescer, and the like may be used to emit yellowish green, yellow, or orange light.

### Second Embodiment

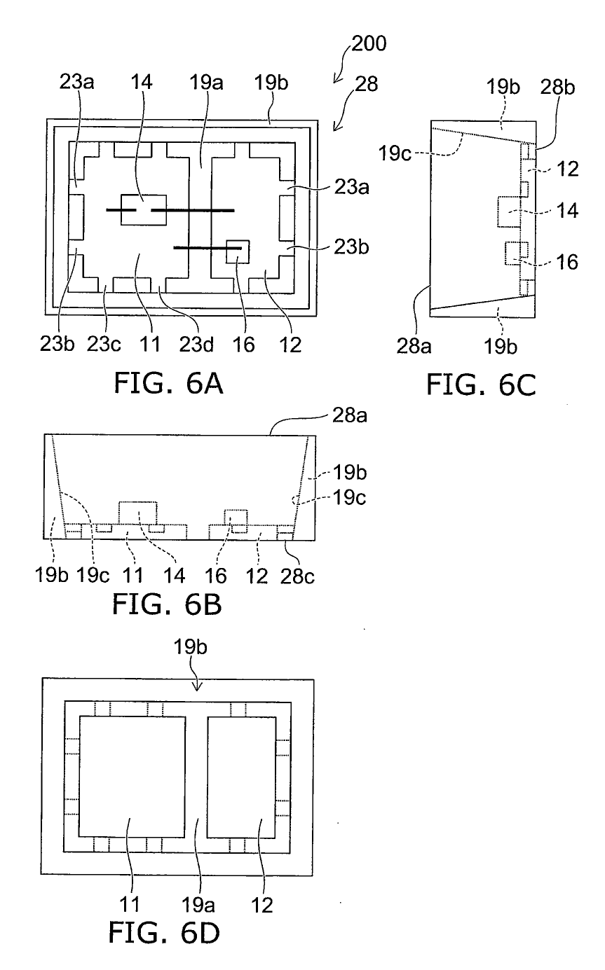

FIGS. 6A to 6D are schematic views illustrating a semiconductor light emitting device 200 according to a second embodiment. FIG. 6A is a plan view; FIG. 6B is a front view; FIG. 6C is a side view; and FIG. 6D is a bottom plan view.

In the semiconductor light emitting device 200, the cross-sectional area of the first resin 19a of a resin package 28 in a cross-section parallel to the front surface of the leadframe 11 enlarges from the front surface of the leadframe 11 toward the front surface of the first resin 19a opposite to the leadframe 11.

In other words, as illustrated in FIGS. 6A to 6C, an inner surface 19c of the second resin 19b on the first resin 19a side is provided to tilt. Thereby, the light radiated from the LED 14 is reflected in the direction of an upper surface 28a of the resin package 28; and the light output of the semiconductor light emitting device 200 is increased.

As illustrated in FIG. 6D, in this embodiment as well, the back surface of the leadframe 11 to which the LED is affixed and the back surface of the leadframe 12 are exposed at a back surface 28b of the resin package 28. The leadframe 11 and the leadframe 12 that include the linking portions (the suspension pins) 23a to 23e are positioned on the inner side of the outer edge of the resin package 28 when viewed in plan by projection onto a plane parallel to the back surface 28b. In other words, the end surfaces of the linking portions (the suspension pins) are not exposed at the side surface of the resin package 28.

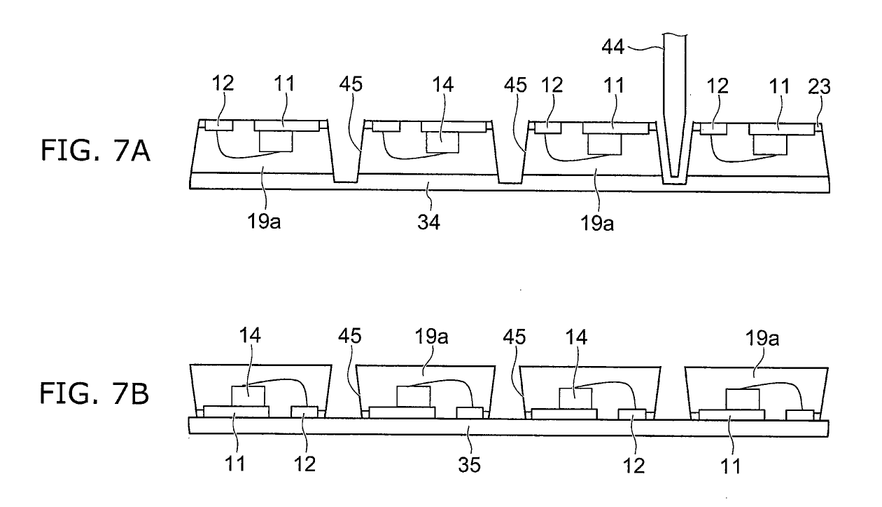

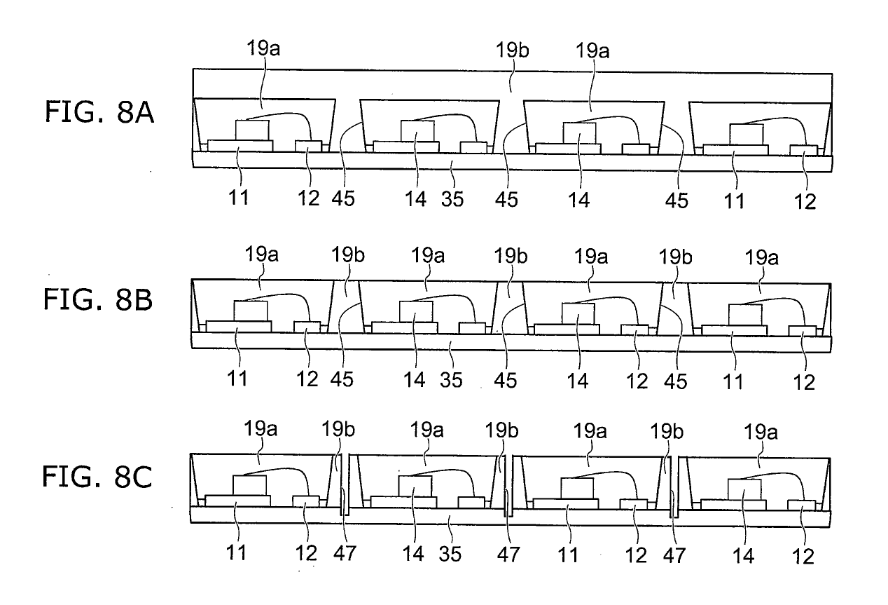

Manufacturing processes of the semiconductor light emitting device 200 will now be described with reference to FIGS. 7A and 7B and FIGS. 8A to 8C. FIG. 7A to FIG. 8C are cross-sectional views that schematically illustrate the processes. The processes prior to the processes illustrated in FIG. 7A are the same as the processes illustrated in FIGS. 2A and 2B.

In this embodiment as illustrated in FIG. 7A, the metal plate 23 and the first resin 19a are divided by a dicing blade 44 having a tapered configuration in which the width of the dicing blade 44 is narrower toward the tip. Thereby, a trench 45 can be made with a width that narrows from the metal plate 23 toward the dicing sheet 34. The trench 45 is made along the outer circumference of the resin packages 28.

Then, as illustrated in FIG. 7B, another dicing sheet 35 is adhered to the back surface of the metal plate 23; and the dicing sheet 34 is peeled from the front surface of the first resin 19a. Thereby, the metal plate 23 is transferred in the state of the front surface side (the first major surface side) being oriented upward.

Continuing as illustrated in FIG. 8A, the second resin 19b is formed from the front surface side of the metal plate 23 to cover the first resin 19a and the trench 25. At this time, the second resin 19b can be filled into the interior of the trench 45 from the narrow side of the trench 45 by vacuum forming.

Then, as illustrated in FIG. 8B, the second resin formed on the upper surface of the first resin 19a is removed to leave the second resin 19b in the trench 25. For example, the front surface of the first resin 19a is exposed by polishing or grinding the second resin 19b.

Continuing as illustrated in FIG. 8C, the second resin 19b is cut along the extension directions of the trench 25. Thereby, the resin packages 28 can be formed such that the outer edges of the first resin 19a are covered with the second resin 19b.

In this embodiment as well, the second resin 19b may be filled after increasing the width of the trench 45 by expanding the dicing sheet 35. Thereby, the width of the second resin 19b can be wider.

Although the semiconductor light emitting device and the method for manufacturing semiconductor light emitting device according to the first and second embodiments are described above, the embodiments are not limited to the examples recited above. It is also possible to use other methods. For example, it is possible to use screen printing, a dispenser, and the like when filling the second resin into the trench provided at the outer circumferences of the resin packages.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A method for manufacturing a semiconductor light emitting device, comprising:
preparing a metal plate including a plurality of first frames and a plurality of second frames, the first frames being disposed alternately with the second frames to be apart from the second frames, a light emitting element being affixed to each of the first frames and connected via a metal wire to an adjacent second frame;
forming a first resin on a first major surface of the metal plate to cover the first frames, the second frames, and the light emitting elements;
making a trench from a second major surface side opposite to the first major surface to delineate resin packages by dividing the metal plate and the first resin;
filling a second resin into an interior of the trench from the first major surface side; and
forming the resin packages by dividing the second resin along the trench, an outer edge of the first resin being covered with the second resin.

2. The method according to claim 1, further comprising:
transferring the metal plate onto a sheet by adhering the divided second major surface side of the metal plate to the sheet with the first major surface side of the metal plate oriented upward;
forming the second resin from the first major surface side to cover the first resin and the trench; and
removing the second resin formed on a front surface of the first resin to leave the second resin in the trench.

3. The method according to claim 2, wherein the sheet is expanded to fill the second resin into the trench having a wider width.

4. The method according to claim 2, wherein a front surface of the second resin is polished or ground to expose the front surface of the first resin.

5. The method according to claim 1, wherein the second resin includes a reflective material configured to reflect light radiated by the light emitting elements.

6. The method according to claim 5, wherein directivity is controlled by changing an amount of the reflective material included in the second resin.

7. The method according to claim 5, wherein directivity is controlled by changing a thickness of the second resin.

8. The method according to claim 1, wherein the first resin includes a same material as the second resin.

9. The method according to claim 1, wherein the first resin and the second resin include silicone.

10. The method according to claim 1, wherein the first resin includes at least one selected from a silicate-based fluorescer, a YAG-based fluorescer, and a sialon-based fluorescer.

11. The method according to claim 1, wherein the trench is made by dividing the first resin using a dicing blade.

12. The method according to claim 11, wherein the dicing blade has a tapered configuration, a width of the dicing blade being narrower toward a tip of the dicing blade.

13. The method according to claim 1, wherein the second resin is divided using a dicing blade having a width narrower than the trench.

14. The method according to claim 1, wherein the device includes a component affixed to at least one selected from the first frame and the second frame at a higher temperature than the affixing of the light emitting element.

15. The method according to claim 1, wherein the light emitting elements are affixed to the first frames via one selected from a silver paste and a resin paste.

16. The method according to claim 1, wherein the light emitting elements are affixed to the first frames by solder or eutectic solder.

17. The method according to claim 1, wherein the first frames and the second frames are flat plates arranged in the same plane, and silver plating is performed on front surfaces of the first frames and the second frames.

18. A semiconductor light emitting device, comprising:
a first frame;
a light emitting element affixed to the first frame;
a second frame disposed apart from the first frame, the second frame being electrically connected to an electrode of the light emitting element via a metal wire; and
a resin package including a first resin and a second resin, the first resin being configured to cover the light emitting element, the first frame, and the second frame, the second resin being configured to cover an outer edge of the first resin and reflect light emitted by the light emitting element,
a cross-sectional area of the first resin in a cross-section parallel to a front surface of the first frame being configured to enlarge from the front surface of the first frame toward a front surface of the first resin opposite to the first frame,
a back surface of the first frame and a back surface of the second frame being exposed at one surface of the resin package, the back surface of the first frame being on a side opposite to the front surface of the first frame having the affixed light emitting element, the back surface of the second frame being on a side opposite to the front surface of the second frame having the connected metal wire,
the first frame and the second frame being positioned on an inner side of an outer edge of the resin package when viewed in plan by projection onto a plane parallel to the one surface.

19. The device according to claim 18, wherein the first resin includes at least one selected from a silicate-based fluorescer, a YAG-based fluorescer, and a sialon-based fluorescer.

20. The device according to claim 18, wherein the second resin includes a reflective material configured to reflect light radiated by the light emitting element.
